(19) United States
(12) Patent Application Publication
(10) Pub. No.: US 2015/0257281 A1
(43) Pub. Date: Sep. 10, 2015

(54) METHOD FOR FORMING A VIA STRUCTURE USING A DOUBLE-SIDE LASER PROCESS

(71) Applicant: Marvell World Trade Ltd., St. Michael (BB)

(72) Inventors: Huahung Kao, San Jose, CA (US); Shiann-Ming Liou, Campbell, CA (US)

(21) Appl. No.: 14/642,098

(22) Filed: Mar. 9, 2015

Related U.S. Application Data
(60) Provisional application No. 61/950,738, filed on Mar. 10, 2014.

(51) Int. Cl. H05K 3/40; H05K 1/11; H05K 3/46; H05K 1/02

(52) U.S. Cl. CPC H05K 3/4084; H05K 1/0284; H05K 1/116; H05K 3/4655; H05K 2201/0195; H05K 2201/0338; H05K 2201/0394; H05K 2201/09554; H05K 2201/096; H05K 2201/09827

(57) ABSTRACT

Embodiments include a multi-layer apparatus comprising a first dielectric layer, a second dielectric layer, a third dielectric layer and a fourth dielectric layer, wherein one or more of the dielectric layers include metal layers. The multi-layer apparatus further comprises a first via coupling a first metal layer and a second metal layer, a second via coupling the second metal layer and a fourth metal layer, a third via coupling the first metal layer and the second metal layer, and a fourth via coupling the third metal layer and the fourth metal layer. The first via is contiguous with the second via and the third via is contiguous with the fourth via. At least some of the vias have different depths relative to one another.

### CROSS REFERENCE TO RELATED APPLICATIONS

This claims priority to U.S. Provisional Patent Application No. 61/950,738, filed on Mar. 10, 2014, which is incorporated herein by reference in its entirety.

### TECHNICAL FIELD

Embodiments of the present disclosure relate to a microelectronic device, and in particular to multi-layered electronic devices that include via structures created by a double-sided laser process.

### BACKGROUND

Many microelectronic devices or chips are multi-layer devices that can be made up of multiple substrates or dielectric layers and metal layers, along with other layers and components such as, for example, insulating layers, redistribution layers (RDLs), bond pads, etc. In order to electrically couple the various layers and components, in particular, the metal layers, any RDLs, bond pads, etc., via structures (generally referred to as vias) are created within such a multi-layer device and generally extend vertically through the various layers. Vias are generally created with some kind of drilling process and then filled with a conductive material such as, for example, metal. Examples of drilling processes that may be used include, but are not limited to, mechanical drilling processes, laser processes, etc. One particular example of a drilling process that may be used is referred to as a double-side laser process that can be done with a single laser for a 2-step drilling process. One side of a substrate is drilled first with the laser. The substrate is then flipped over and the other side of the substrate is drilled with the laser. However, such a double-side laser process is generally only feasible with single substrates that include only two metal layers. Thus, a more complicated and expensive build-up of layers is needed for many multi-layer microelectronic devices, where each substrate is drilled with one of either a mechanical drilling process or a laser drilling process and then the layers are coupled together such that each layer's drilled vias are properly aligned with other vias in other layers.

### SUMMARY

In various embodiments, the present disclosure provides a method of making a multilayer substrate, where the method comprises providing a first dielectric layer, patterning a first side of the first dielectric layer to provide a first metal layer, and patterning a second side of the first dielectric layer to provide a second metal layer. The method further comprises providing a second dielectric layer and a third dielectric layer, patterning a first side of the second dielectric layer to provide a third metal layer, and patterning a first side of the third dielectric layer to provide a fourth metal layer. The method also comprises coupling a second side of the second dielectric layer to the first side of the first dielectric layer, coupling a second side of the third dielectric layer to the second side of the first dielectric layer, and creating vias between the metal layers via a double-side laser process. At least some of the vias have different depths relative to one another such that a first via couples the first metal layer and the second metal layer and a second via couples the second metal layer and the fourth metal layer, and a third via couples the first metal layer and the second metal layer and a fourth via couples third metal layer and the fourth metal layer. The first via is contiguous with the second via and the third via is contiguous with the fourth via.

In various embodiments, the present disclosure also provides a multi-layer apparatus comprising a first dielectric layer, wherein a first side of the first dielectric layer comprises a first metal layer, and wherein a second side of the first dielectric layer comprises a second metal layer; a second dielectric layer, wherein a first side of the second dielectric layer comprises a third metal layer, and wherein a second side of the second dielectric layer is coupled to the first side of the first dielectric layer; and a third dielectric layer, wherein a first side of the third dielectric layer comprises a fourth metal layer, and wherein a second side of the third dielectric layer is coupled to the second side of the first dielectric layer. The multi-layer apparatus further comprises a first via coupling the first metal layer and the second metal layer, a second via coupling the second metal layer and the fourth metal layer, a third via coupling the first metal layer and the second metal layer, and a fourth via coupling the third metal layer and the fourth metal layer. The first via is contiguous with the second via and the third via is contiguous with the fourth via. At least some of the vias have different depths relative to one another.

### BRIEF DESCRIPTION OF THE DRAWINGS

Embodiments of the present disclosure will be readily understood by the following detailed description in conjunction with the accompanying drawings. To facilitate this description, like reference numerals designate like structural elements. Various embodiments are illustrated by way of example and not by way of limitation in the figures of the accompanying drawings.

FIGS. 1A-1C schematically illustrate cross-sectional views of examples of multi-layer substrates, in accordance with an embodiment.

FIG. 2 is a flow diagram of an example method for making a multi-layer apparatus, in accordance with an embodiment.

### DETAILED DESCRIPTION

In accordance with various embodiments, a multi-layered substrate or printed circuit board (PCB) is drilled such that via structures within the substrate have different depths with respect to one another. For example, a via extending from a top surface of the substrate may extend from a first metal layer on the top surface of the substrate only to a depth of a second metal layer (or slightly deeper than the second metal layer) within the substrate and electrically couple the first metal layer with the second metal layer, while a second via may extend from a fourth metal layer on a bottom surface of the substrate only to a depth of the second metal layer (or slightly deeper than the second metal layer, i.e., the depth of the first via and the depth of the second via need to deep enough to allow both vias to form a channel that can be filled with metal to electrically connect the desired metal layers) and electrically couple the fourth metal layer with the second metal layer. Thus, the first via would only extend a depth between the first and second metal layers, while the second via would extend a depth between the fourth metal layer and the second metal layer. This can allow for the substrate to be drilled in a single step with a double-side laser process, where the first and second vias are created by a top laser and a bottom laser, respectively.

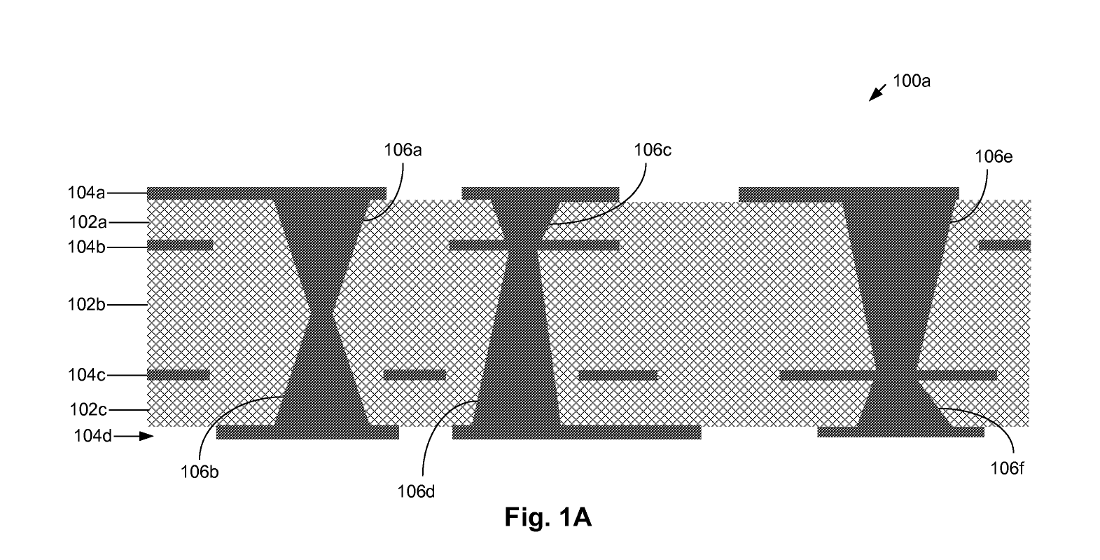

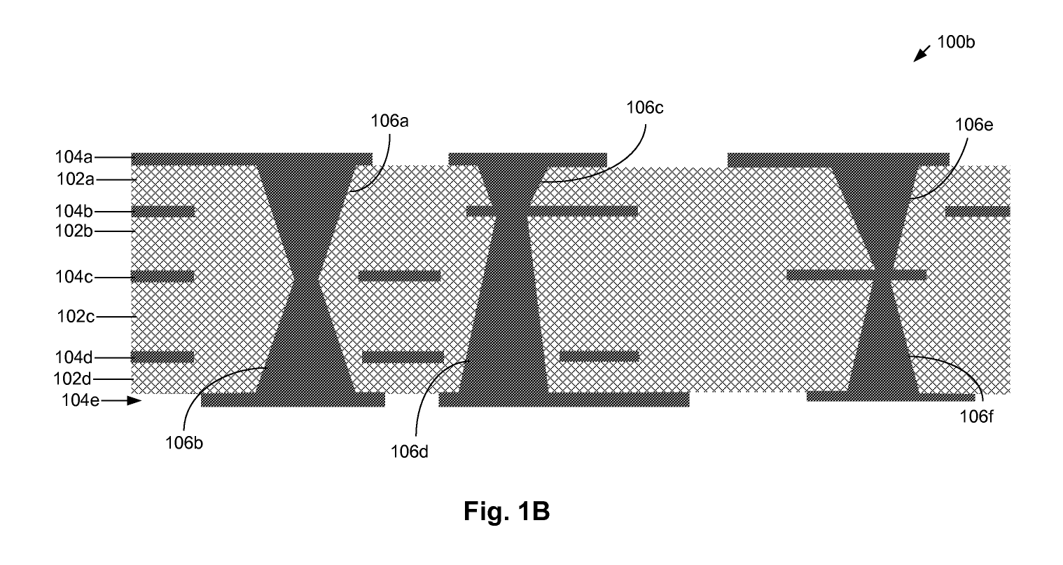

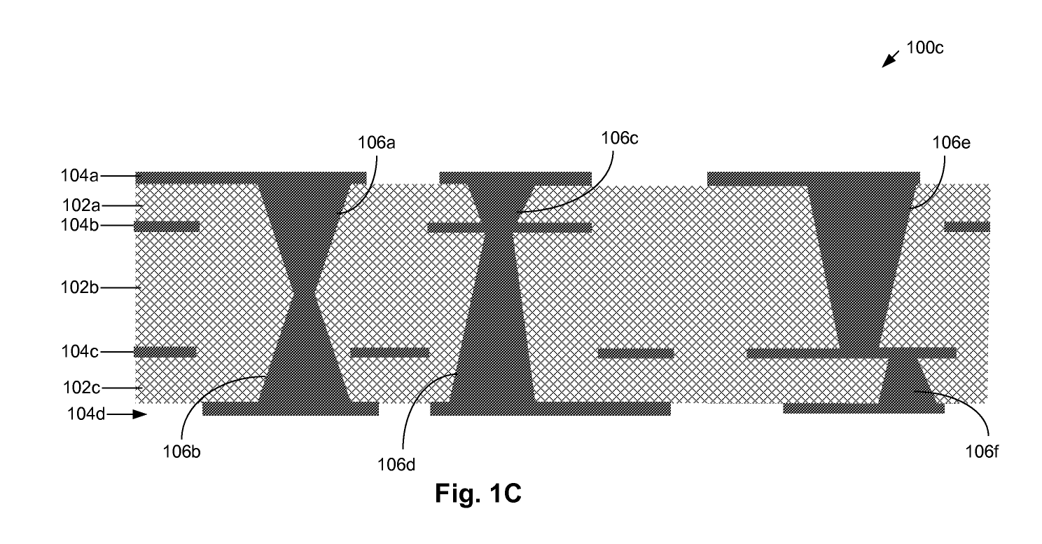

FIG. 1A schematically illustrates a cross-sectional view of an example of a substrate or PCB 100a that includes multiple layers in the form of substrates 102 and metal layers 104. In the example of FIG. 1A, three dielectric layers 102a, 102b and 102c are provided, while four metal layers 104a, 104b, 104c and 104d are provided. A first metal layer 104a is included on a surface of the first dielectric layer 102a, a second metal layer 104b is included between the first dielectric layer 102a and the second dielectric layer 102b, a third metal layer 104c is included between the second dielectric layer 102b and the third dielectric layer 102c, and a fourth metal layer 104d is included on a surface of the third dielectric layer 102c. Other layers are generally included in the substrate or PCB 100a such as, for example, insulating layers, redistribution layers (RDLs), solder mask, adhesion layers, etc., but are not illustrated for clarity. Likewise, bond pads, bump pads and ball pads are generally included on the substrate or PCB 100a to allow for wire bond connections, flip chip connections and solder ball connections to other devices and substrates, but are not illustrated for clarity.

As can be seen in FIG. 1A, vias 106 are provided to couple the various metal layers. A first via 106a and second via 106b are contiguous and electrically couple the first metal layer 104a with the fourth metal layer 104d. A third via 106c electrically couples the first metal layer 104a with the second metal layer 104b, while a fourth via 106d electrically couples the fourth metal layer 104d with the second metal layer 104b. Thus, the third and fourth vias 106c, 106d are contiguous. A fifth via 106e electrically couples the first metal layer 104a with the third metal layer 104c, while a sixth via 106f electrically couples the fourth metal layer 104d with the third metal layer 104c. Thus, the fifth and sixth vias 106e, 1061 are contiguous.

In accordance with various embodiments, the vias 106 are created via a double-side laser process. Thus, a first or top laser creates the first via 106a, while a second or bottom laser creates the second via 106b. The substrate 100a is then moved (or alternatively, an apparatus that includes the top and bottom lasers is moved relative to the substrate 100a) and the top laser creates the third via 106c, while the bottom laser creates the fourth via 106d. Finally, the substrate 100a is moved again (or alternatively, an apparatus that includes the top and bottom lasers is moved again relative to the substrate 100a) and the side laser creates the fifth via 106e, while the bottom laser creates the sixth via 106f. Alternatively, the top laser can create the vias 106a, 106c and 106e, and then the bottom laser can create the vias 106b, 106d and 106f. Accordingly, as can be seen in FIG. 1A, the various vias 106 are at different depths with respect to one another. The double-side laser process provides a smaller via and smaller via land to provide much needed flexibility for a tight layout of the substrate 100a. Once the vias 106 have been drilled, the vias 106 are filled with an appropriate conductive material such as, metal.

In accordance with various embodiments, one or more of the dielectric layers 102 are patterned with the metal layers 104 using a known process that includes depositing and etching a masking layer (not illustrated) on a dielectric layer 102 to outline a desired pattern for a metal layer 104 on the dielectric layer 102 and then depositing the metal layer 104 on the dielectric layer 102. A dielectric layer 102 may include one metal layer 104 located on a single surface of the dielectric layer 102. A dielectric layer 102 may also include two metal layers 104, with one metal layer 104 being located on a first surface of the dielectric layer 102 and the other metal layer 104 being located on a second surface of the dielectric layer 102 opposite to the first surface. Alternatively, one or more of the dielectric layers 102 may be pre-patterned with a desired metal layer 104 or metal layers 104 include thereon. Thus, such pre-patterned dielectric layers 102 may be obtained from a separate vendor or may be created by the entity making the substrate or PCB 100a. In accordance with an embodiment, the dielectric layers 102 are coupled to one another using a lamination process that includes providing an epoxy or other adhesive on the dielectric layers 102 and pressing the dielectric layers 102 together with at least some pressure. The lamination process may also include applying some heat while pressing the dielectric layers 102 together.

While FIG. 1A schematically illustrates an example of a substrate or PCB 100a that includes three dielectric layers 102 and four metal layers 104, more or fewer dielectric layers 102 and metal layers 104 may be utilized as desired and depending upon the application. For example, FIG. 1B schematically illustrates a cross-sectional view of an example of a substrate or PCB 100b that includes four dielectric layers 102a, 102b, 102c and 102d, and five metal layers 104a, 104b, 104c, 104d and 104e. A first via 106a and second via 106b electrically couples the first metal layer 104a with the fifth metal layer 104e, while a third via 106c electrically couples the first metal layer 104a with the second metal layer 104b. As can be seen, the first and second vias are contiguous, as are the third and fourth vias. A fourth via 106d electrically couples the fifth metal layer 104e with the second metal layer 104b. A fifth via 106e electrically couples the first metal layer 104a with the third metal layer 104c, while a sixth via 106f electrically couples the fifth metal layer 104e with the third metal layer 104c. The example embodiment of FIG. 1B may be created in a manner similar to the manner described with respect to FIG. 1A.

FIG. 1C schematically illustrates a cross-sectional view of an example of a substrate or PCB 100c that is similar to the embodiment of FIG. 1A. As can be seen, the fifth via 106e electrically couples the first metal layer 104a with the third metal layer 104c, while the sixth via 106f electrically couples the fourth metal layer 104d with the third metal layer 104c. However, the fifth via 106e is offset with respect to the sixth via 106f. Thus, the fifth and sixth vias 106e, 106f are offset relative to one another, but are still contiguous through the third metal layer 104c. Such an embodiment is useful when space is limited and it is generally not possible to align a top via/via pad and a bottom via/via pad. The vias can be partially or completely offset.

As previously noted, in accordance with an embodiment, a double-side laser process may be used to create the vias 106. The pulsing of the lasers during the drilling of the vias with the double-side laser process results in the vias 106 having a tapered shape, as can be seen in the figures. Additionally, while the example embodiments of FIGS. 1A-1C illustrate six vias 106a, 106b, 106c, 106d, 106e and 106f, it should be noted that more of fewer vias may be included as desired and depending on the application.

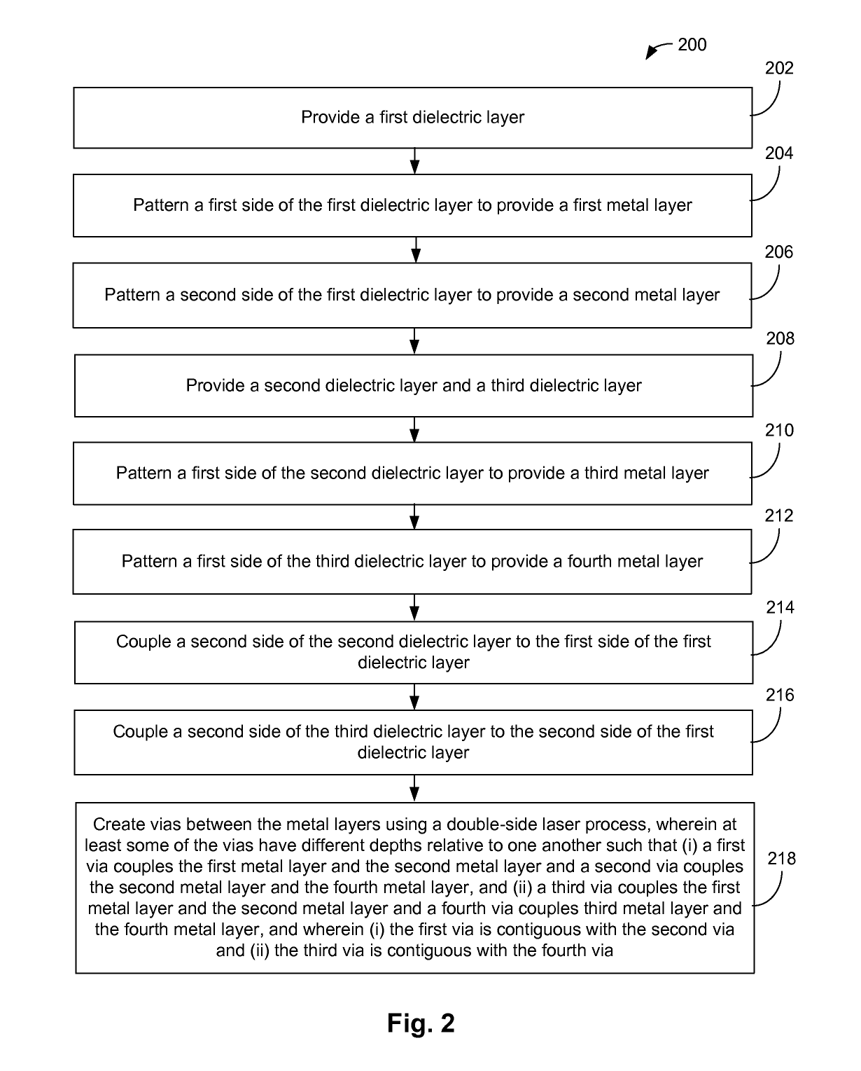

FIG. 2 is a flow diagram of an example method for making a multi-layer apparatus, in accordance with an embodiment. At 202, a first dielectric layer is provided. At 204, a first side of the first dielectric layer is patterned to provide a first metal layer. At 206, a second side of the first dielectric layer is patterned to provide a second metal layer. At 208, a second dielectric layer and a third dielectric layer are provided. At 210, a first side of the second dielectric layer is patterned to provide a third metal layer. At 212, a first side of the third dielectric layer is patterned to provide a fourth metal layer. At 214, a second side of the second dielectric layer is coupled to the first side of the first dielectric layer. At 216, a second side of the third dielectric layer is coupled to the second side of the first dielectric layer. At 218, vias are created between the metal layers via a double-side laser process, wherein at least some of the vias have different depths relative to one another such that (i) a first via couples the first metal layer and the second metal layer and a second via couples the second metal layer and the fourth metal layer, and (ii) a third via couples the first metal layer and the second metal layer and a fourth via couples third metal layer and the fourth metal layer, and wherein (i) the first via is contiguous with the second via and (ii) the third via is contiguous with the fourth via.

Although certain embodiments have been illustrated and described herein, a wide variety of alternate and/or equivalent embodiments or implementations calculated to achieve the same purposes may be substituted for the embodiments illustrated and described without departing from the scope of the present invention. This application is intended to cover any adaptations or variations of the embodiments discussed herein. Therefore, it is manifestly intended that embodiments in accordance with the present invention be limited only by the claims and the equivalents thereof.

What is claimed is:

1. A method of making a multilayer substrate, the method comprising:
providing a first dielectric layer;
patterning a first side of the first dielectric layer to provide a first metal layer;
patterning a second side of the first dielectric layer to provide a second metal layer;
providing a second dielectric layer and a third dielectric layer;
patterning a first side of the second dielectric layer to provide a third metal layer;
patterning a first side of the third dielectric layer to provide a fourth metal layer;
coupling a second side of the second dielectric layer to the first side of the first dielectric layer;
coupling a second side of the third dielectric layer to the second side of the first dielectric layer;
creating vias between the metal layers via a double-side laser process,
wherein at least some of the vias have different depths relative to one another such that (i) a first via couples the first metal layer and the second metal layer and a second via couples the second metal layer and the fourth metal layer, and (ii) a third via couples the first metal layer and the second metal layer and a fourth via couples third metal layer and the fourth metal layer, and
wherein (i) the first via is contiguous with the second via and (ii) the third via is contiguous with the fourth via.

2. The method of claim 1, wherein the second dielectric layer is pre-patterned to provide the third metal layer.

3. The method of claim 1, wherein the third dielectric layer is pre-patterned to provide the fourth metal layer.

4. The method of claim 1, wherein the first dielectric layer is pre-patterned to provide the first and second metal layers.

5. The method of claim 1, wherein:
coupling the second side of the second dielectric layer to the first side of the first dielectric layer comprises laminating the second side of the second dielectric layer the first side of the first dielectric layer; and
coupling the second side of the third dielectric layer to the second side of the first dielectric layer comprises laminating the second side of the third dielectric layer to the first side of the first dielectric layer.

6. The method of claim 1, further comprising:
providing a fourth dielectric layer;
patterning a first side of the fourth dielectric layer to provide a fifth metal layer;
coupling a second side of the fourth dielectric layer to a second side of the third dielectric layer;
further creating vias between the metal layers via a double-side laser process such that a fifth via couples the fifth metal layer and the first metal layer.

7. The method of claim 5, wherein the fourth dielectric layer is pre-patterned to provide the fifth metal layer.

8. The method of claim 5, wherein coupling the second side of the fourth dielectric layer to the second side of the third dielectric layer comprises laminating the second side of the fourth dielectric layer to the second side of the third dielectric layer.

9. The method of claim 1, wherein at least one of (i) the first and second vias or (ii) the third and fourth vias are offset with respect to each other.

10. A multi-layer apparatus comprising:
a first dielectric layer, wherein a first side of the first dielectric layer comprises a first metal layer, and wherein a second side of the first dielectric layer comprises a second metal layer;
a second dielectric layer, wherein a first side of the second dielectric layer comprises a third metal layer, and wherein a second side of the second dielectric layer is coupled to the first side of the first dielectric layer;
a third dielectric layer, wherein a first side of the third dielectric layer comprises a fourth metal layer, and wherein a second side of the third dielectric layer is coupled to the second side of the first dielectric layer;
a first via coupling the first metal layer and the second metal layer;
a second via coupling the second metal layer and the fourth metal layer;
a third via coupling the first metal layer and the second metal layer; and
a fourth via coupling the third metal layer and the fourth metal layer,
wherein (i) the first via is contiguous with the second via and (ii) the third via is contiguous with the fourth via, and
wherein at least some of the vias have different depths relative to one another.

11. The apparatus of claim 10, wherein the second dielectric layer is pre-patterned to provide the third metal layer.

12. The apparatus of claim 10, wherein the third dielectric layer is pre-patterned to provide the fourth metal layer.

13. The apparatus of claim 10, wherein the first dielectric layer is pre-patterned to provide the first and second metal layers.

14. The apparatus of claim 10, wherein:
the second side of the second dielectric layer is laminated to the first side of the first dielectric layer; and
the second side of the third dielectric layer is laminated to the second side of the first dielectric layer.

15. The apparatus of claim 10, further comprising:
a fourth dielectric layer, wherein a first side of the fourth dielectric layer comprises a fifth metal layer, and wherein a second side of the fourth dielectric layer is coupled to a second side of the third dielectric layer; and
a fifth via coupling the fifth metal layer and the first metal layer.

16. The apparatus of claim 15, wherein the fourth dielectric layer is pre-patterned to provide the fifth metal layer.

17. The apparatus of claim 10, wherein the second side of the fourth dielectric layer is laminated to the first side of the third dielectric layer.

18. The apparatus of claim 10, wherein at least one of (i) the first and second vias or (ii) the third and fourth vias are offset with respect to each other.

19. The apparatus of claim 10, wherein each of the first, second, third and fourth vias have a tapered shape.

20. The apparatus of claim 10, wherein the apparatus comprises a printed circuit board (PCB).
